(19) United States
(12) Patent Application Publication
(10) Pub. No.: US 2026/0352230 A1
(43) Pub. Date: Nov. 5, 2026

(54) METHOD AND DEVICE WITH DECOMPRESSION

(71) Applicant: Samsung Electronics Co., Ltd., Suwon-si (KR)

(72) Inventors: Arnab ROY, Bengaluru (IN); Madhur JUNEJA, Bengaluru (IN); Kiran Kolar CHANDRASEKHARAN, Bengaluru (IN); Nilay Nitin BIRMOLE, Bengaluru (IN); Wooram YANG, Suwon-si (KR); Jihoon NAM, Suwon-si (KR)

(73) Assignee: Samsung Electronics Co., Ltd., Suwon-si (KR)

(21) Appl. No.: 19/661,816

(22) Filed: Apr. 29, 2026

(30) Foreign Application Priority Data
May 2, 2025 (IN) 202541042818
Jul. 31, 2025 (KR) 10-2025-0105267

(51) Int. Cl. H03M 7/30

(52) U.S. Cl. CPC H03M 7/6023; H03M 7/6005

(57) ABSTRACT

A processor-implemented method includes allocating a first compression block set of a plurality of compression block sets to a first parallel decoder of a plurality of parallel decoders, determining whether a first compression block of the first compression block set has data dependency on decompression of another compression block, and decompressing the first compression block using a decompression manner determined as either a sequential decompression or a non-sequential decompression, the decompression manner being determined based on whether the first compression block has the data dependency.

### CROSS-REFERENCE TO RELATED APPLICATIONS

This application claims the benefit under 35 USC § 119(a) of Indian Patent Application No. 202541042818, filed on May 2, 2025 in the Indian Patent Office, and Korean Patent Application No. 10-2025-0105267, filed on Jul. 31, 2025 in the Korean Intellectual Property Office, the entire disclosures of which are incorporated herein by reference for all purposes.

### BACKGROUND

### 1. Field

The following description relates to a method and device with decompression.

### 2. Description of Related Art

Modern high-performance computing demands enhanced memory capacity, increased bandwidths, and optimized computational efficiency within focused areas. Compression techniques may aim to reduce memory capacity and bandwidth burden. To use compressed data in applications, decompression of the compressed data may be required. Decompression may refer to a process of returning compressed data to an uncompressed state before compression.

Various data compression techniques may involve analyzing historical (or past) data to identify similar byte sequences. For example, methods such as Huffman coding and run-length encoding (RLE) may efficiently encode frequently recurring bytes to reduce redundancy. Dictionary-based algorithms, such as Lempel-Ziv (LZ) variant, may replace recurring patterns of bytes with references to previously verified data.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one or more general aspects, a processor-implemented method includes allocating a first compression block set of a plurality of compression block sets to a first parallel decoder of a plurality of parallel decoders, determining whether a first compression block of the first compression block set has data dependency on decompression of another compression block, and decompressing the first compression block using a decompression manner determined as either a sequential decompression or a non-sequential decompression, the decompression manner being determined based on whether the first compression block has the data dependency.

The plurality of parallel decoders may be decoders that simultaneously perform decompression of compression blocks allocated to each parallel decoder, and the data dependency on the decompression of the other compression block may be dependency on decompressed data generated by the decompression of the other compression block.

The method may include allocating a second compression block set of the plurality of compression block sets to a second parallel decoder of the plurality of parallel decoders, and the determining of whether the first compression block has the data dependency may include determining whether the first compression block has the data dependency on decompression of the second compression block of the second compression block set.

The decompressing of the first compression block may include decompressing the first compression block using the non-sequential decompression in response to the first compression block having the data dependency on the decompression of the second compression block, and decompressing the first compression block using the sequential decompression in response to the first compression block not having the data dependency on the decompression of the second compression block.

The method may include verifying a decompression status of the second compression block in response to the first compression block having the data dependency on the decompression of the second compression block, and decompressing the first compression block using the sequential decompression in response to the first compression block having the data dependency on the decompression of the second compression block and the decompression status indicating completion of the decompression of the second compression block, and the decompressing of the first compression block using the non-sequential decompression may include decompressing the first compression block using the non-sequential decompression in response to the first compression block having the data dependency on the decompression of the second compression block and the decompression status not indicating the completion of the decompression of the second compression block.

The decompressing of the first compression block using the non-sequential decompression may include skipping decompression of a portion of the first compression block having the data dependency, and sequentially decompressing a portion of the first compression block not having the data dependency.

The decompressing of the first compression block using the non-sequential decompression may include monitoring a decompression status of the second compression block, and decompressing a portion of the first compression block, in which the decompression is skipped, in response to the decompression status indicating completion of the decompression of the second compression block.

The monitoring of the decompression status may include monitoring the decompression status of the second compression block before performing decompression of each compression block of the first compression block set comprising the first compression block.

The monitoring of the decompression status may include monitoring whether reference decompressed data corresponding to the second compression block to be used for decompression of the portion of the first compression block having the data dependency is available, based on decompression of one or more portions of the second compression block, and the decompressing of the portion of the first compression block, in which the decompression is skipped, may include decompressing the portion of the first compression block, in which the decompression is skipped, in response to the decompression status indicating availability of the reference decompressed data.

A number of parallel decoders of the plurality of parallel decoders may be less than a number of compression blocks of the plurality of compression block sets.

The method may include determining the plurality of compression block sets by grouping the compression blocks of the plurality of compression block sets based on the number of compression blocks of the plurality of compression block sets and the number of parallel decoders of the plurality of parallel decoders.

The method may include generating metadata corresponding to each parallel decoder of the plurality of parallel decoders, the metadata may include position information corresponding to a compression block set of the plurality of compression block sets corresponding to each parallel decoder of the plurality of parallel decoders, and the decompressing of the first compression block may include decompressing the first compression block using the sequential decompression or the non-sequential decompression manner based on metadata corresponding to the first parallel decoder and whether the first compression block has the data dependency.

The generating of the metadata may include receiving metadata corresponding to compression blocks of the plurality of compression block sets, and generating metadata corresponding to each parallel decoder of the plurality of parallel decoders by selecting a portion of the metadata corresponding to the compression blocks of the plurality of compression block sets.

In one or more general aspects, an electronic device includes one or more processors comprising processing circuitry, and memory comprising one or more storage media storing instructions that, when executed individually or collectively by the one or more processors, cause the electronic device to allocate a first compression block set of a plurality of compression block sets to a first parallel decoder of a plurality of parallel decoders, determine whether a first compression block of the first compression block set has data dependency on decompression of another compression block, and decompress the first compression block using a decompression manner determined as either a sequential decompression or a non-sequential decompression, the decompression manner being determined based on whether the first compression block has the data dependency.

The execution of the instructions may cause the electronic device to allocate a second compression block set of the plurality of compression block sets to a second parallel decoder of the plurality of parallel decoders, and for the determining of whether the first compression block has the data dependency, determine whether the first compression block has the data dependency on decompression of the second compression block of the second compression block set.

For the decompressing of the first compression block, the execution of the instructions may cause the electronic device to decompress the first compression block using the non-sequential decompression in response to the first compression block having the data dependency on the decompression of the second compression block, and decompress the first compression block using the sequential decompression in response to the first compression block not having the data dependency on the decompression of the second compression block.

For the decompressing of the first compression block using the non-sequential decompression, the execution of the instructions may cause the electronic device to skip decompression of a portion of the first compression block having the data dependency, and sequentially decompress a portion of the first compression block not having the data dependency.

For the decompressing of the first compression block, the execution of the instructions may cause the electronic device to monitor a decompression status of the second compression block, and decompress a portion of the first compression block, in which the decompression is skipped, in response to the decompression status indicating completion of the decompression of the second compression block.

For the monitoring of the decompression status, the execution of the instructions may cause the electronic device to monitor the decompression status of the second compression block before performing decompression of each compression block of the first compression block set comprising the first compression block.

In one or more general aspects, a processor-implemented method includes skipping decompression of a portion of a compression block, in response to the portion having data dependency on decompression of another compression block, sequentially decompressing another portion of the compression block not having the data dependency, in response the portion having the data dependency, and decompressing the portion having the data dependency, in response to the decompression of the other compression block being completed.

Other features and aspects will be apparent from the following detailed description, the drawings, and the claims.

### BRIEF DESCRIPTION OF THE DRAWINGS

FIG. 1 illustrates an example of an operation of an electronic device that performs decompression according to one or more embodiments.

FIGS. 2A and 2B illustrate an example of a compression block before decompression is performed according to one or more embodiments.

FIG. 3 illustrates an example of a process of decompressing a plurality of compression blocks in parallel using a plurality of parallel decoders according to one or more embodiments.

FIG. 4 illustrates an example of data dependency of a compression block according to one or more embodiments.

FIG. 5 illustrates an example of a process of decompressing a first compression block in a non-sequential decompression manner according to one or more embodiments.

FIG. 6 illustrates an example of a process of determining a decompression method of a first compression block as a sequential decompression manner or a non-sequential decompression manner according to one or more embodiments.

FIG. 7 illustrates an example of a process of generating metadata corresponding to a plurality of parallel decoders according to one or more embodiments.

FIG. 8 illustrates an example of a decompression method using a plurality of parallel decoders according to one or more embodiments.

FIG. 9 illustrates an example of a configuration of an electronic device that performs decompression using a plurality of parallel decoders according to one or more embodiments.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Although terms such as "first," "second," and "third", or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Throughout the specification, when a component or element is described as being "on", "connected to," "coupled to," or "joined to" another component, element, or layer it may be directly (e.g., in contact with the other component, element, or layer) "on", "connected to," "coupled to," or "joined to" the other component, element, or layer or there may reasonably be one or more other components, elements, layers intervening therebetween. When a component, element, or layer is described as being "directly on", "directly connected to," "directly coupled to," or "directly joined" to another component, element, or layer there can be no other components, elements, or layers intervening therebetween. Likewise, expressions, for example, "between" and "immediately between" and "adjacent to" and "immediately adjacent to" may also be construed as described in the foregoing.

The terminology used herein is for describing various examples only and is not to be used to limit the disclosure. The articles "a," "an," and "the" are intended to include the plural forms as well, unless the context clearly indicates otherwise. As non-limiting examples, terms "comprise" or "comprises," "include" or "includes," and "have" or "has" specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms "comprise" or "comprises," "include" or "includes," and "have" or "has" specify the presence of stated features, numbers, operations, members, elements, and/or combinations thereof, other embodiments may exist where one or more of the stated features, numbers, operations, members, elements, and/or combinations thereof are not present.

As used herein, the term "and/or" includes any one and any combination of any two or more of the associated listed items. The phrases "at least one of A, B, and C", "at least one of A, B, or C", and the like are intended to have disjunctive meanings, and these phrases "at least one of A, B, and C", "at least one of A, B, or C" (e.g., each phrase may include any one of the respective items alone, all of the items listed together, and all possible combinations thereof), and the like also include examples where there may be one or more of each of A, B, and/or C (e.g., any combination of one or more of each of A, B, and C), unless the corresponding description and embodiment necessitates such listings (e.g., "at least one of A, B, and C") to be interpreted to have a conjunctive meaning.

Unless otherwise defined, all terms, including technical and scientific terms, used herein have the same meaning as commonly understood by one of ordinary skill in the art to which this disclosure pertains and specifically in the context on an understanding of this disclosure. It will be further understood that terms, such as those defined in commonly-used dictionaries, should be interpreted as having a meaning that is consistent with their meaning in the context of the relevant art and specifically in the context of this disclosure, and will not be interpreted in an idealized or overly formal sense unless expressly so defined herein.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term "may" herein with respect to an example or embodiment (e.g., as to what an example or embodiment may include or implement) means that at least one example or embodiment exists where such a feature is included or implemented, while all examples are not limited thereto. The use of the terms "example", "embodiment", and "example embodiment" herein have a same meaning (e.g., the phrasing 'in an or one example' has a same meaning as 'in an or one embodiment" and 'in an or one example embodiment'), and "one or more examples" has a same meaning as "one or more embodiments" and "one or more example embodiments". Still further, each of multiple or all separately described an/one "example", "embodiment", "example embodiment", as well as "examples", "embodiments", "example embodiments", herein may be included, in combination, in a same embodiment in any combination.

Hereinafter, examples will be described in detail with reference to the accompanying drawings. When describing the examples with reference to the accompanying drawings, like reference numerals refer to like elements and a repeated description related thereto will be omitted.

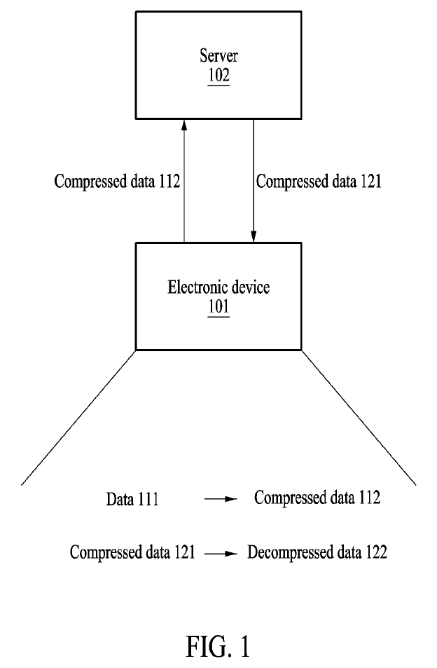

FIG. 1 illustrates an example of an operation of an electronic device that performs decompression according to one or more embodiments. Referring to FIG. 1, an electronic device 101 may perform compression and decompression. The electronic device 101 may generate compressed data 112 by performing compression based on data 111. The data 111 may include original data to be compressed. The data 111 may include data received from a user (e.g., a user of the electronic device 101). The electronic device 101 may transmit and receive data to and from a server 102 via a network. The data 111 may include data received from the server 102.

The electronic device 101 may generate the compressed data 112 by compressing the data 111 using a compression technique. For example, the electronic device 101 may generate the compressed data 112 by compressing the data 111 by utilizing a compression technique using a dictionary-based compression algorithm such as the Lempel-Ziv (LZ) 4 compression technique. The LZ4 compression technique may be a deformed compression technique of the LZ77 compression technique. The compression technique may be LZ4, but is not limited thereto. The compressed data 112 may include a plurality of compression blocks. The compression block may be, but is not limited to, an LZ4 compression block generated by the LZ4 compression technique.

The electronic device 101 may transmit the compressed data 112 to the server 102 and store the compressed data 112 in the server 102. The electronic device 101 may transmit the plurality of compression blocks of the compressed data 112 to the server 102 and store the plurality of compression blocks in the server 102. The electronic device 101 may generate metadata corresponding to the compressed data 112. The electronic device 101 may generate the metadata corresponding to the plurality of compression blocks of the compressed data 112. The electronic device 101 may transmit the metadata together with the compressed data 112 to the server 102 and store the metadata together with the compressed data 112 in the server 102. The metadata corresponding to the plurality of compression blocks may include position information of each compression block of the plurality of compression blocks. The position information of each compression block of the plurality of compression blocks may include information about a position of the decompressed data corresponding to each compression block in the original data.

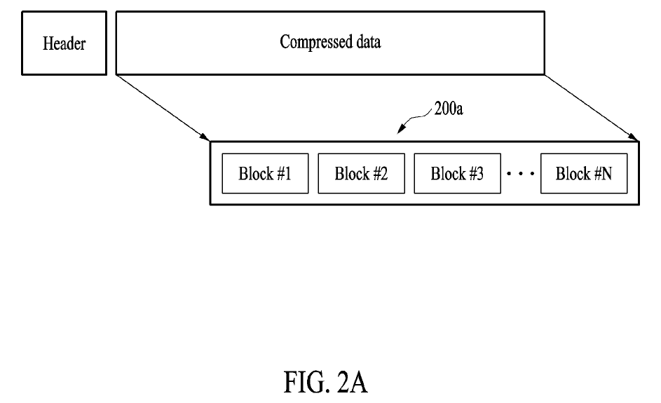

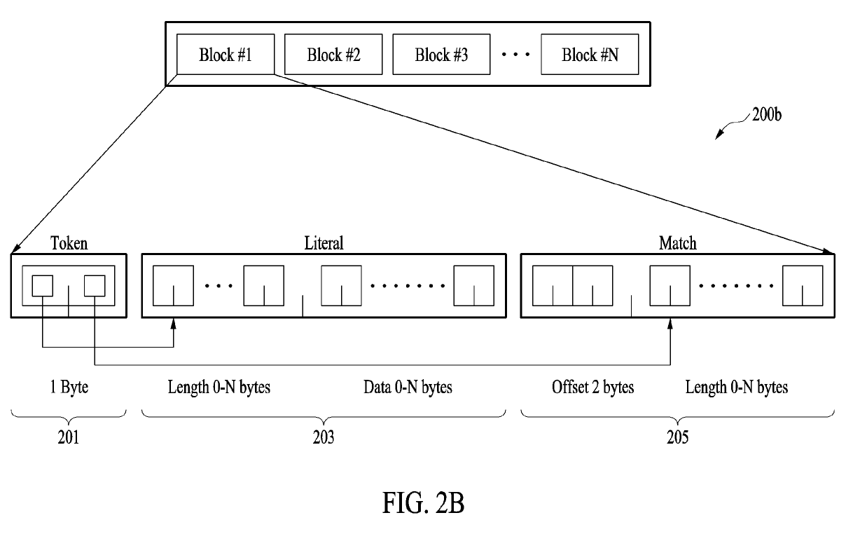

FIGS. 2A and 2B illustrate an example of a compression block before decompression is performed according to one or more embodiments. Referring to FIG. 2A, the compression technique may generate compressed data by compressing the original data. The compressed data may correspond to the compressed data 112 and/or compressed data 121 of FIG. 1. The compressed data may include a chain 200a of compression blocks. For example, the chain 200a of compression blocks may include blocks #1 to #N. The compression block may have an unfixed data size.

Referring to FIG. 2B, a compression block 200b may include three sections of a token section 201, a literal section 203, and a match section 205. The token section 201 may include at least some information about a literal length and at least some information about a match length. The literal section 203 may include the literal length and literal data. The literal data may include data of a non-recurring portion of the original data. The literal length may include information about a length of the literal data.

The match section 205 may include a match offset and a match length. The match offset may include information about a position where the match data starts. The match length may include information about a length of the match data starting from the position indicated by the match offset. The match data may represent recurring data (or a pattern) in the original data. To reduce redundancy within the original data, the compression block may not include the match data of the original data. By not including the match data, the compression block 200b may have a smaller size than a portion corresponding to the compression block 200b in the original data. An electronic device (e.g., the electronic device 101 of FIG. 1) may decompress the match data of the compression block by referring to data that matches preceding match data of the match data in the original data based on the match offset and the match length of the compression block.

The match offset of the match section 205 of the compression block 200b may indicate a position corresponding to a compression block other than the compression block 200b. A match offset of a match section of a compression block other than the compression block 200b may indicate a position corresponding to the compression block 200b. When the match offset of one compression block indicates the position of the data of the other compression block, decompressed data generated by decompression of the other compression block may be used to refer to the data at that position.

When the decompressed data corresponding to the other compression block is to be used for the decompression of the compression block, it may be expressed that the compression block has data dependency on the decompression of the other compression block. When one compression block has data dependency on the decompression of another compression block, it may be determined that the decompression of the other compression block is to be performed first. The data dependency on the decompression of the other compression block may include dependency on the decompressed data generated by the decompression of the other compression block. The data dependency may be referred to as inter-block data dependency.

Referring back to FIG. 1, the electronic device 101 may generate decompressed data 122 by performing decompression based on the compressed data 121. The compressed data 121 may include the compressed data 112 compressed by the electronic device 101. The compressed data 121 may include data received from a user. The electronic device 101 may receive the compressed data 121 from the server 102. The electronic device 101 may receive metadata corresponding to the compressed data 121 together with the compressed data 121 from the server 102. The electronic device 101 may generate the decompressed data 122 by performing the decompression based on the metadata and the compressed data 121.

The compressed data 121 may include a plurality of compression blocks. The electronic device 101 may generate the decompressed data 122 by decompressing the plurality of compression blocks using a decoder. A decoder may be implemented as a software module or an algorithm that performs the decompression of compression blocks. The electronic device 101 may sequentially decompress the plurality of compression blocks using the decoder so as to refer to preceding data.

In an example, the electronic device 101 may manage data for performing the decompression of a portion of the compressed data 121 having data dependency. For example, data for performing the decompression of the portion of the compressed data 121 having data dependency may include an outstanding read pointer (ORDPTR), an outstanding write pointer (OWRPTR), and an outstanding write size (OWRSZ). The ORDPTR may include information about a position of the portion having the data dependency within the compressed data 121. The OWRPTR may include information about a position of data of other compressed data 121 that is to be referred to in order to decompress the portion of the compressed data 121 having data dependency. The OWRSZ may include information about a size of the data of other compressed data 121 that is to be referred to in order to decompress the portion of the compressed data 121 having data dependency.

The electronic device 101 may allocate the plurality of compression blocks to the plurality of parallel decoders. The electronic device 101 may decompress the plurality of compression blocks in parallel using the plurality of parallel decoders. The plurality of parallel decoders may be decoders that simultaneously perform decompression of compression blocks allocated to each parallel decoder. Each decoder of the plurality of parallel decoders may be executed simultaneously in different threads by one or more processors of the electronic device 101. By performing the decompression of the plurality of compression blocks in parallel, the electronic device 101 of one or more embodiments may increase the overall decompression speed and the efficiency of decompression.

When the electronic device 101 decompresses the plurality of compression blocks in parallel using the plurality of parallel decoders, sequential decompression of the plurality of compression blocks may not be guaranteed. For example, the decompression of a first compression block allocated to a first parallel decoder may be performed before the decompression of a second compression block allocated to a second parallel decoder, and the second compression block may be a compression block preceding the first compression block within the plurality of compression blocks. Since the sequential decompression of the plurality of compression blocks is not guaranteed, some compression blocks of the plurality of compression blocks may not be decompressed immediately. For example, when the first compression block allocated to the first parallel decoder has data dependency on the decompression of the second compression block allocated to the second parallel decoder, the first compression block may not be decompressed until the second compression block is decompressed.

In order to decompress match data of one compression block (e.g., the first compression block allocated to the first parallel decoder), when the decompression process of a parallel decoder (e.g., the first parallel decoder), to which the one compression block is allocated, is temporarily stalled until the decompression of a compression block allocated to another parallel decoder (e.g., the second compression block allocated to the second parallel decoder) is completed, the efficiency of parallel decompression may be reduced.

The electronic device 101 of one or more embodiments may prevent a decrease in efficiency of the parallel decompression caused by the data dependency by using a non-sequential decompression manner to decompress compression blocks. The non-sequential decompression manner may refer to a method that does not sequentially decompress compression blocks. According to the non-sequential decompression manner, the electronic device 101 may skip the decompression of a portion of a compression block having data dependency. According to the non-sequential decompression method, the electronic device 101 may perform, before completing decompression of a compression block, decompression of a following compression block of the compression block. One or more examples of the non-sequential decompression manner will be described in more detail below.

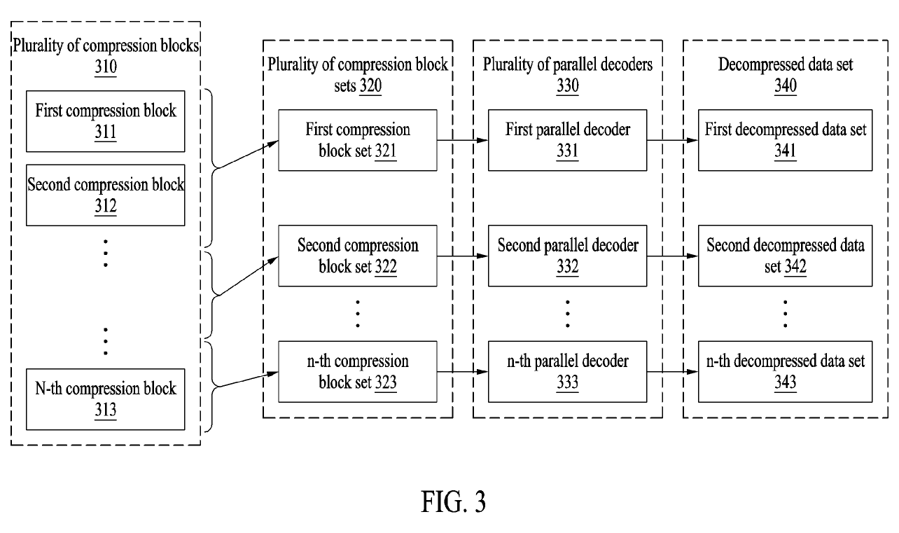

FIG. 3 illustrates an example of a process of decompressing a plurality of compression blocks in parallel using a plurality of parallel decoders according to one or more embodiments. Referring to FIG. 3, an electronic device may determine a plurality of compression block sets 320 by grouping a plurality of compression blocks 310. The electronic device may correspond to the electronic device 101 of FIG. 1. The electronic device may determine a plurality of compression block sets by grouping a plurality of compression blocks based on the number (e.g., the total number) of compression blocks of the plurality of compression blocks 310 and the number (e.g., the total number) of parallel decoders of a plurality of parallel decoders 330. The number of parallel decoders of the plurality of parallel decoders 330 may be less than the number of compression blocks of the plurality of compression blocks 310. The electronic device may determine the plurality of compression block sets 320 by grouping the plurality of compression blocks 310 such that the number of compression block sets of the plurality of compression block sets 320 is equal to the number of parallel decoders of the plurality of parallel decoders 330.

The plurality of compression blocks 310 may include a first compression block 311, a second compression block 312, to an N-th compression block 313. N may be the number of compression blocks of the plurality of compression blocks 310. The plurality of compression block sets 320 may include a first compression block set 321, a second compression block set 322, to an n-th compression block set 323. n may be the number of compression block sets of the plurality of compression block sets 320. The number of compression block sets, n, may be equal to the number of parallel decoders of the plurality of parallel decoders 330.

The electronic device may group the plurality of compression blocks so that each compression block set of the plurality of compression block sets 320 includes the equal number of compression blocks based on the number of compression blocks of the plurality of compression blocks 310. The electronic device may determine a set size of each compression block set of the plurality of compression block sets 320 based on the number of compression blocks of the plurality of compression blocks 310 and the number of parallel decoders of the plurality of parallel decoders 330. The set size may indicate the number of compression blocks included in the compression block set.

When the number of compression blocks of the plurality of compression blocks 310 is divisible by the number of parallel decoders of the plurality of parallel decoders 330, the electronic device may determine the result of the division as the set size of each compression block set. For example, when N and n are 40 and 8, respectively, the set size of each compression block set of the plurality of compression block sets 320 may be determined as 5, and the first compression block set 321 may include a first compression block 311, a second compression block 312, a third compression block (not shown), a fourth compression block (not shown), and a fifth compression block (not shown).

When the number of compression blocks of the plurality of compression blocks 310 is not exactly divisible by the number of parallel decoders of the plurality of parallel decoders 330, the electronic device may determine the set sizes of some compression block sets of the plurality of compression block sets 320 to be values that are larger than the set sizes of the remaining compression block sets by 1. For example, each integer of a remainder of N divided by n may be included in a different compression block set. For example, when N and n are 82 and 4, respectively, the remainder of 82 divided by 4 is 2, and the set sizes of the plurality of compression block sets 320 may be determined as 21, 21, 20, and 20, respectively. Accordingly, in an example, the set size of each of the plurality of compression block sets 320 may be greater than or equal to N divided by n.

A compression block may have an unfixed data size. In an example, the electronic device may group the plurality of compression blocks 310 such that each compression block set of the plurality of compression block sets 320 has the equal data size as much as possible based on the data size of each compression block of the plurality of compression blocks 310 rather than the number of compression blocks of the plurality of compression blocks 310.

The electronic device may allocate the plurality of compression block sets 320 to the plurality of parallel decoders 330. The plurality of parallel decoders 330 may include a first parallel decoder 331, a second parallel decoder 332, to an n-th parallel decoder 333. Each parallel decoder of the plurality of parallel decoders 330 may be implemented as a software module or algorithm that performs decompression of a compression block. The plurality of compression block sets 320 and the plurality of parallel decoders 330 may correspond one-to-one. The electronic device may allocate each compression block set of the plurality of compression block sets 320 to a parallel decoder of the plurality of parallel decoders 330. The electronic device may allocate the first compression block set 321, the second compression block set 322, and the n-th compression block set 323 of the plurality of compression block sets 320 to the first parallel decoder 331, the second parallel decoder 332, and the n-th parallel decoder 333 of the plurality of parallel decoders 330, respectively.

The electronic device may generate a decompressed data set 340 by decompressing a compression block set allocated to each decoder of the plurality of parallel decoders 330. The decompressed data set 340 may include a first decompressed data set 341, a second decompressed data set 342, to an n-th decompressed data set 343. Each decompressed data set of the decompressed data set 340 may include a decompressed data set corresponding to compression blocks of a respective compression block set of the plurality of compression block sets 320. The decompressed data corresponding to compression blocks may be included. For example, the first decompressed data set 341 may include decompressed data corresponding to compression blocks of the first compression block set 321.

Each parallel decoder of the plurality of parallel decoders 330 may perform decompression in parallel (simultaneously) with other decoders to generate a decompressed data set. For example, the first parallel decoder 331 of the plurality of parallel decoders 330 may decompress the first compression block set 321 of the plurality of compression block sets 320 to generate the first decompressed data set 341 in parallel with the second parallel decoder 332 of the plurality of parallel decoders 330 decompressing the second compression block set 322 of the plurality of compression block sets 320 to generate the second decompressed data set 342.

The electronic device may receive metadata together with the plurality of compression blocks 310 from a server (e.g., the server 102 of FIG. 1). In an example, the metadata received from the server may be metadata corresponding to the plurality of compression blocks 310. In an example, the metadata received from the server may be metadata corresponding to the plurality of parallel decoders 330. When the metadata received from the server is metadata corresponding to the plurality of compression blocks 310, the electronic device may generate metadata corresponding to the plurality of parallel decoders 330 based on the metadata corresponding to the plurality of compression blocks 310. The electronic device may decompress the plurality of compression block sets 320 based on the metadata to generate the decompressed data set 340.

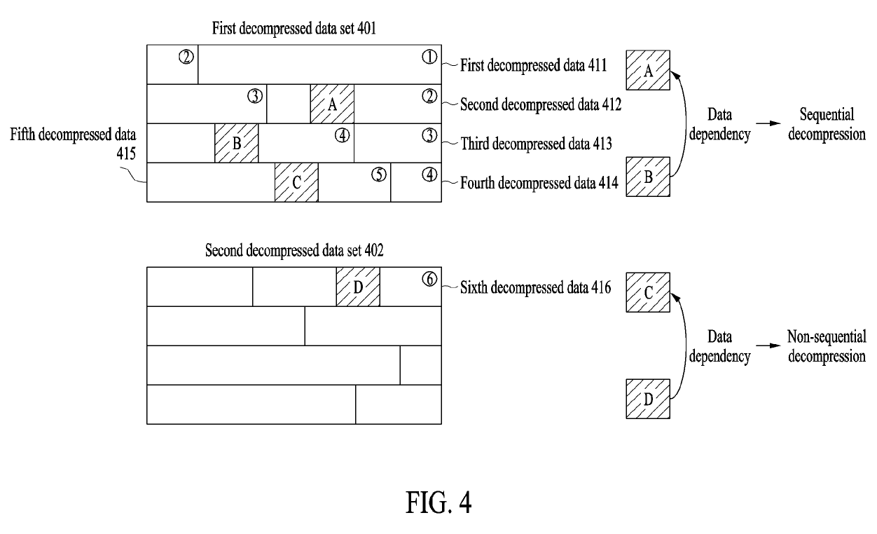

FIG. 4 illustrates an example of data dependency of a compression block according to one or more embodiments. Referring to FIG. 4, a first decompressed data set 401 and a second decompressed data set 402 may each include a decompressed data set corresponding to a compression block set allocated to one parallel decoder. The first decompressed data set 401 may include a decompressed data set (e.g., the first decompressed data set 341 of FIG. 3) corresponding to a first compression block set (e.g., the first compression block set 321) allocated to a first parallel decoder (e.g., the first parallel decoder 331 of FIG. 3). The second decompressed data set 402 may include a decompressed data set (e.g., the second decompressed data set 342 of FIG. 3) corresponding to a second compression block set (e.g., the second compression block set 322) allocated to a second parallel decoder (e.g., the second parallel decoder 332 of FIG. 3).

The first decompressed data set 401 may include first decompressed data 411, second decompressed data 412, third decompressed data 413, fourth decompressed data 414, and fifth decompressed data 415. The second decompressed data set 402 may include sixth decompressed data 416. The first decompressed data 411, the second decompressed data 412, the third decompressed data 413, the fourth decompressed data 414, the fifth decompressed data 415, and the sixth decompressed data 416 may be sequential decompressed data within the entire decompressed data. For example, the second decompressed data 412 may be decompressed data after the first decompressed data 411 (e.g., after the first decompressed data 411 in sequential data including the first decompressed data 411 and the second decompressed data 412), and the sixth decompressed data 416 may be decompressed data generated after the fifth decompressed data 415.

The first decompressed data 411, the second decompressed data 412, the third decompressed data 413, the fourth decompressed data 414, the fifth decompressed data 415, and the sixth decompressed data 416 may each include decompressed data respectively corresponding to a first compression block, a second compression block, a third compression block, a fourth compression block, a fifth compression block, and a sixth compression block. The first compression block, the second compression block, the third compression block, the fourth compression block, the fifth compression block, and the sixth compression block may be sequential compression blocks within a plurality of compression blocks (e.g., the plurality of compression blocks 310 of FIG. 3). For example, the second compression block may be a compression block after the first compression block, and the sixth compression block may be a compression block after the fifth compression block.

To decompress the compression block, the electronic device may refer to decompressed data corresponding to a compression block before the compression block. The second decompressed data 412 may include data A. The fourth decompressed data 414 may include data B. The data A and the data B may correspond to recurring data in original data. In order to decompress the fourth compression block corresponding to the fourth decompressed data 414, and to generate data D, the electronic device may refer to the second decompressed data 412 corresponding to the second compression block. The fifth decompressed data 415 may include data C. The sixth decompressed data 416 may include the data D. The data C and the data D may correspond to recurring data in original data. In order to decompress the sixth compression block corresponding to the sixth decompressed data 416 and to generate the data B, the electronic device may refer to the fifth decompressed data 415 corresponding to the fifth compression block. Data that is a target of reference for decompression of other compression blocks within the decompressed data (e.g., the data A within the second decompressed data 412 and the data C within the fifth decompressed data 415) may be referred to as reference decompressed data.

In order for the electronic device to refer to the decompressed data corresponding to a previous compression block during the decompression of a compression block, the decompressed data corresponding to the previous compression block may be determined. In this case, the compression block may be expressed as having data dependency on the decompression of the compression block preceding it. In order for the electronic device to refer to the second decompressed data 412 corresponding to the second compression block during decompression of the fourth compression block, the decompressed data corresponding to the second compression block may be determined. The fourth compression block corresponding to the fourth decompressed data 414 may have data dependency on the decompression of the second compression block corresponding to the second decompressed data 412. In order for the electronic device to refer to the fifth decompressed data 415 corresponding to the fifth compression block during decompression of the sixth compression block, the decompressed data corresponding to the fifth compression block may be determined. The sixth compression block corresponding to the sixth decompressed data 416 may have data dependency on the decompression of the fifth compression block corresponding to the fifth decompressed data 415.

When the compression block does not have data dependency, the electronic device may decompress the compression block in a sequential decompression manner. The sequential decompression may refer to a method in which the decompression of a next compression block is not performed on the parallel decoder until the decompression of the compression block on the parallel decoder is completed. The first compression block corresponding to the first decompressed data 411 may not have data dependency on other compression blocks. The electronic device may decompress the first compression block in the sequential decompression manner. The electronic device may not perform the decompression of the second compression block following the first compression block on the parallel decoder until the decompression of the first compression block is completed. The electronic device may perform the decompression of the second compression block following the first compression block on the parallel decoder when the decompression of the first compression block is completed.

When the compression block has the data dependency, the electronic device may decompress the compression blocks in the non-sequential decompression manner. The non-sequential decompression may be a method of performing the decompression of a next compression block on the parallel decoder without completing the decompression of the compression block on the parallel decoder. The sixth compression block corresponding to the sixth decompressed data 416 may have the data dependency on another compression block (e.g., the fifth compression block corresponding to the fifth decompressed data 415). The electronic device may perform the decompression of a compression block following the sixth compression block on the parallel decoder without completing the decompression of the sixth compression block on the parallel decoder.

When the compression block has the data dependency on the decompression of another compression block, the decompression of the compression block having the data dependency may not be completed before the decompression of the other compression block is performed. When the electronic device decompresses compression blocks having the data dependency in a sequential decompression manner, the decompression of the compression blocks on the parallel decoder may need to be temporarily stopped. By decompressing compression blocks having the data dependency in the non-sequential decompression manner, the electronic device of one or more embodiments may improve the efficiency of parallel decompression because the decompression of compression blocks on the parallel decoder is not stopped.

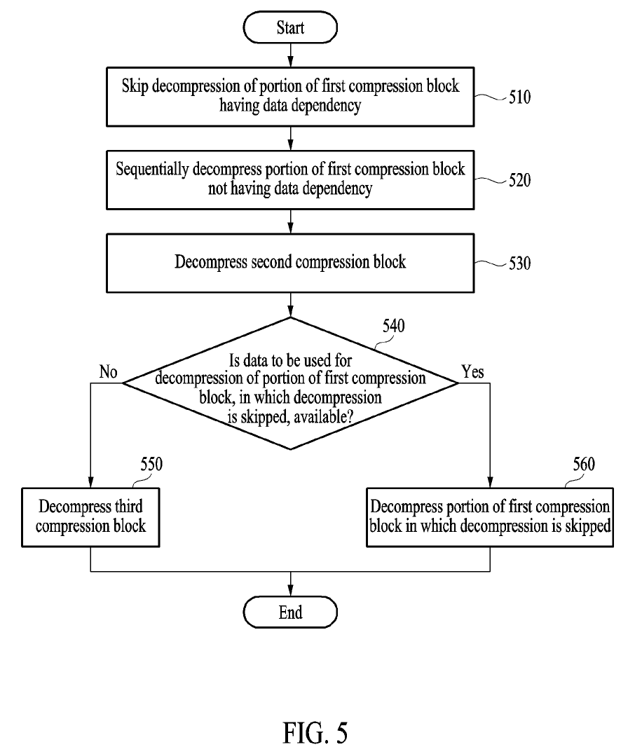

FIG. 5 illustrates an example of a process of decompressing a first compression block in a non-sequential decompression manner according to one or more embodiments. Although one or more of operations of FIG. 5 are illustrated as being performed sequentially, one or more of the operations may be performed in a different order, one or more of the operations may be omitted, two or more of the operations may be performed in parallel or simultaneously, and/or other operations may be additionally performed without departing from the spirit and scope of the described embodiments.

Referring to FIG. 5, in operation 510, the electronic device may skip decompression of a portion of a first compression block having data dependency (e.g., in response to the portion having the data dependency). The electronic device may correspond to the electronic device 101 of FIG. 1. The first compression block may have the data dependency on the decompression of another compression block. In order to decompress the portion of the first compression block having the data dependency, the electronic device may refer to reference decompressed data corresponding to the other compression block. When the electronic device may not use (may not refer to) reference decompressed data corresponding to another compression block in a first parallel decoder, to which the first compression block is allocated, the electronic device may skip the decompression of the portion of the first compression block having the data dependency.

In operation 520, the electronic device may sequentially decompress the portion of the first compression block having the data dependency. The electronic device may decompress the portion of the first compression block not having the data dependency in the sequential decompression manner. Operation 520 is shown as being performed after operation 510, but may be performed before operation 510 or simultaneously with operation 510, according to examples.

In operation 530, the electronic device may decompress a second compression block. The second compression block may correspond to a compression block after the first compression block. The electronic device may perform the decompression of the second compression block when the decompression of the portion of the first compression block not having the data dependency is completed. The electronic device may decompress the second compression block in the sequential decompression manner or in the non-sequential decompression manner.

In operation 540, the electronic device may monitor whether data to be used for (e.g., required for) the decompression of the skipped portion of the first compression block is available. The data to be used for the decompression of the skipped portion of the first compression block may include reference decompressed data corresponding to another compression block. The reference decompressed data corresponding to the other compression block may include decompressed data to be used for the decompression of the portion of the first compression block having the data dependency.

When the decompression of the other compression block is completed, the electronic device may use the data to be used for the decompression of the skipped portion of the first compression block from the first parallel decoder, to which the first compression block is allocated. When decompressing the other compression block in the non-sequential decompression manner, the electronic device may decompress at least a portion of the other compression block. Even when the decompression of the other compression block is not completed, when at least a portion of the other compression block is decompressed to generate the reference decompressed data, the electronic device may use the data to be used for the decompression of the skipped portion of the first compression block in the first parallel decoder, to which the first compression block is allocated.

The electronic device may monitor a decompression status of the other compression block. The electronic device may monitor the decompression status of the other compression block to monitor whether the reference decompressed data corresponding to the other compression blocks is available. The decompression status may be a state indicating whether the decompression has been performed. For example, when the reference decompressed data corresponding to the other compression block is available (e.g., has been decompressed) in the parallel decoder, to which the first compression block is allocated, as at least a portion of the other compression block is decompressed, the decompression status of the other compression block may indicate the availability of the reference decompressed data. For example, when the decompression of the other compression block is completed, the decompression status of the other compression block may indicate decompression.

The electronic device may periodically monitor whether the reference decompressed data corresponding to the other compression block is available from the first parallel decoder, to which the first compression block is allocated. Before performing the decompression of each compression block (e.g., a second compression block, a third compression block, or a fourth compression block) of a compression block set including the first compression block, the electronic device may monitor whether the reference decompressed data corresponding to the other compression block is available. The electronic device may monitor whether the reference decompressed data corresponding to the other compression block is available in operation 540 before performing the decompression of the third compression block in operation 550. Operation 540 is shown as not being performed before operation 530, but may also be performed before operation 530, or operation 540 may also be performed after operation 550, according to other examples.

In an example, the electronic device may manage a decompression status list of the plurality of compression blocks. When the decompression of the compression block is completed, the decompression status may be displayed as "DONE" in the decompression status list. When the decompression of the compression block has not yet been completed, the decompression status may be displayed as "Not Applicable (NA)" in the decompression status list. When the decompression of the compression block is in progress, the decompression status may be displayed as "IN PROGRESS" in the decompression status list. When the decompression of at least a portion of the compression block is skipped, the decompression status may be displayed as "ACTIVE" in the decompression status list. The electronic device may monitor the decompression status list to monitor whether the data to be used to decompress the skipped portion of the first compression block is available. When the monitored decompression status of the other compression block changes to "DONE," the electronic device may decompress the portion of the first compression block, in which the decompression is skipped, in operation 560.

When the data to be used for the decompression of the portion of the first compression block, in which the decompression is skipped, is not available, the process may proceed to operation 550. In operation 550, the electronic device may decompress the third compression block corresponding to a compression block after the second compression block. When the data to be used for the decompression of the portion of the first compression block, in which the decompression is skipped, is available, the process may proceed to operation 560. In operation 560, the electronic device may decompress the portion of the first compression block, in which the decompression is skipped.

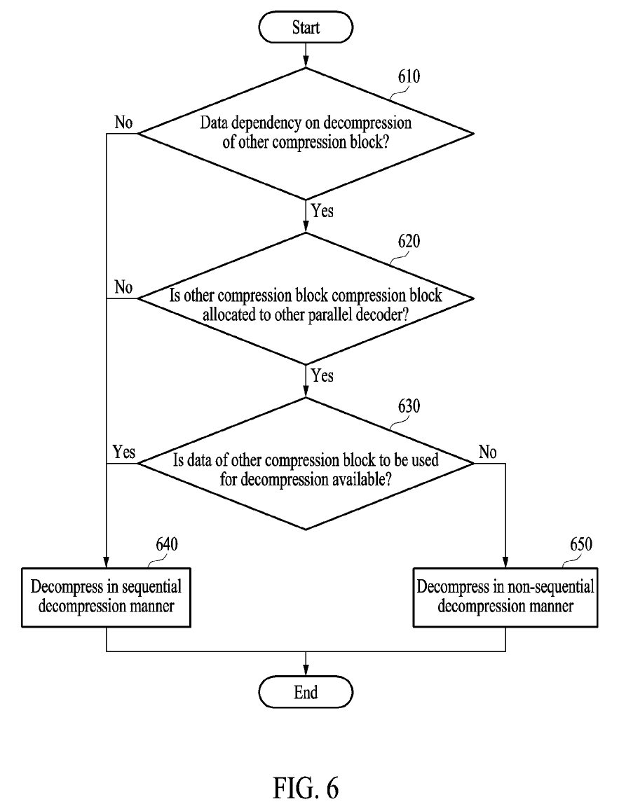

FIG. 6 illustrates an example of a process of determining a decompression method of a first compression block as a sequential decompression manner or a non-sequential decompression manner according to one or more embodiments. Although one or more of operations of FIG. 5 are illustrated as being performed sequentially, one or more of the operations may be performed in a different order, one or more of the operations may be omitted, two or more of the operations may be performed in parallel or simultaneously, and/or other operations may be additionally performed without departing from the spirit and scope of the described embodiments. The electronic device may decompress the first compression block in the sequential decompression manner or in the non-sequential decompression manner. The electronic device may correspond to the electronic device 101 of FIG. 1.

Referring to FIG. 6, in operation 610, the electronic device may determine whether the first compression block has the data dependency on decompressed data of another compression block. When the first compression block does not have the data dependency on the decompressed data of the other compression block, in operation 640, the electronic device may decompress the first compression block in the sequential decompression manner.

When the first compression block has the data dependency on the decompression of the other compression block, in operation 620, the electronic device may verify whether the other compression block is a compression block allocated to another parallel decoder. Based on the verification, the electronic device may determine whether the first compression block has the data dependency on the decompression of the other compression block allocated to the other parallel decoder. For example, the electronic device may determine whether the first compression block allocated to a first parallel decoder has the data dependency on the decompression of a second compression block allocated to a second parallel decoder.

Even when the first compression block has the data dependency on the decompressed data of the other compression block, when the other compression block is allocated to the same parallel decoder as the first compression block, the decompression of the other compression block may be performed before the decompression of the first compression block. In this case, the electronic device may use the decompressed data corresponding to the other compression block on the parallel decoder during the decompression of the first compression block, and the non-sequential decompression may not be required. When the other compression block is not a compression block allocated to the other parallel decoder, in operation 640, the electronic device may decompress the first compression block in the sequential decompression manner.

Referring again to FIG. 4, a fourth compression block corresponding to the fourth decompressed data 414 may have the data dependency on the decompression of the second compression block corresponding to the second decompressed data 412. The second compression block corresponding to the second decompressed data 412 and the fourth compression block corresponding to the fourth decompressed data 414 may correspond to compression blocks allocated to the same parallel decoder (e.g., the first parallel decoder 331 of FIG. 3). When the electronic device decompresses the fourth compression block corresponding to the fourth decompressed data 414 on the parallel decoder, the decompression of the second compression block corresponding to the second decompressed data 412 has already been performed, so that the electronic device may use the second decompressed data 412 to decompress the fourth compression block corresponding to the fourth decompressed data 414. Since the second compression block corresponding to the second decompressed data 412 and the fourth compression block corresponding to the fourth decompressed data 414 are allocated to the same parallel decoder, the electronic device may decompress the fourth compression block in the sequential decompression manner.

Referring again to FIG. 6, when the other compression block is a compression block allocated to the other parallel decoder, in operation 630, the electronic device may verify whether data of the other compression block to be used for (e.g., required for) the decompression is available. The data of the other compression block to be used for the decompression of the first compression block may be referred to as reference decompressed data corresponding to the other compression block. In order to determine whether the reference decompressed data corresponding to the other compression block is available, the electronic device may verify the decompression status of the other compression block.

Even when the first compression block allocated to the first parallel decoder has the data dependency on decompressed data of the other compression block (e.g., the second compression block) allocated to the other parallel decoder (e.g., the second parallel decoder), when the decompression of all of the other compression blocks is completed, the electronic device may use the decompressed data of the other compression block in the first parallel decoder. When the decompression of all of the other compression blocks is completed, the decompression status of the other compression block may indicate the completion of decompression of the other compression blocks. In this case, the electronic device may use decompressed data corresponding to the other compression block on the parallel decoder during the decompression of the first compression block, and the non-sequential decompression may not be required.

Even when the first compression block allocated to the first parallel decoder has the data dependency on decompressed data of the other compression block (e.g., the second compression block) allocated to the other parallel decoder (e.g., the second parallel decoder), when the reference decompressed data corresponding to the other compression block is generated as at least a portion of the other compression block is decompressed, the electronic device may use the decompressed data of the other compression block in the first parallel decoder. When the other compression block is decompressed in the non-sequential decompression manner, at least a portion of the other compression block may be decompressed. When the reference decompressed data corresponding to the other compression block is generated as at least a portion of the other compression block is decompressed, the decompression status may indicate the availability of the reference decompressed data. In this case, the electronic device may use reference decompressed data corresponding to the other compression block on the parallel decoder during the decompression of the first compression block, and the non-sequential decompression may not be required.

When the data of the other compression block to be used for the decompression of the first compression block is available, in operation 640, the electronic device may decompress the first compression block in the sequential decompression manner. When the data of the other compression block to be used for the decompression of the first compression block is not available, in operation 650, the electronic device may decompress the first compression block in the non-sequential decompression manner.

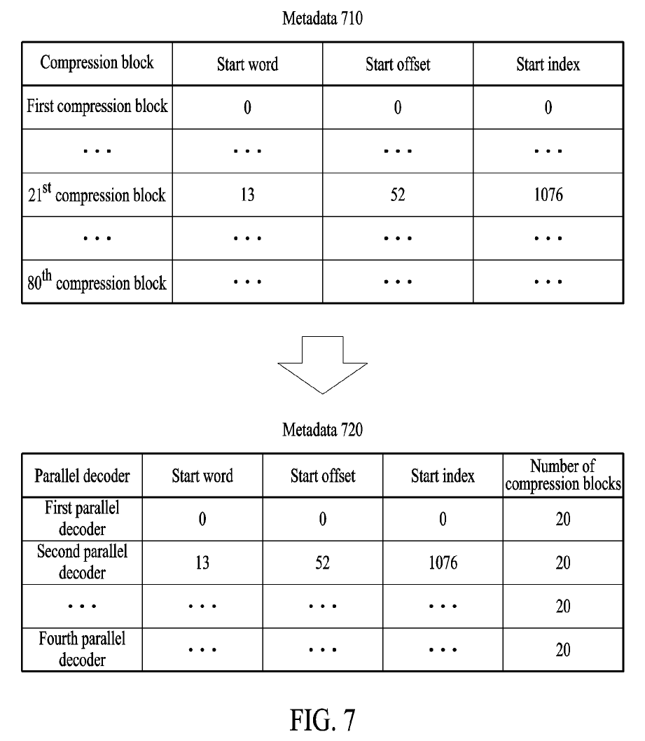

FIG. 7 illustrates an example of a process of generating metadata corresponding to a plurality of parallel decoders according to one or more embodiments. Referring to FIG. 7, metadata 710 may include metadata corresponding to a plurality of compression blocks. The metadata corresponding to the plurality of compression blocks may include metadata corresponding to each compression block of the plurality of compression blocks. The electronic device may receive the metadata 710 along with the plurality of compression blocks. The electronic device may correspond to the electronic device 101 of FIG. 1. FIG. 7 shows an example in which the number of compression blocks of the plurality of compression blocks is 80.

The metadata 710 may include position information corresponding to the plurality of compression blocks. The position information may include a start word, a start offset, and a start index. The start word of the metadata 710 may include information about a first word of decompressed data corresponding to the compression block. The start offset of the metadata 710 may include information about a position of the first word of the decompressed data corresponding to the compression block. The start index of the metadata 710 may include information about a position where the decompressed data corresponding to the compression block among the entire decompressed data starts.

The electronic device may generate metadata 720 based on the metadata 710. The metadata 720 may include metadata corresponding to each parallel decoder of the plurality of parallel decoders. FIG. 7 shows an example in which the number of parallel decoders of the plurality of parallel decoders is 4. The electronic device may generate the metadata 720 by selecting a portion of the metadata 710. The electronic device may select a portion of the metadata 710 based on the number of compression blocks included in a compression block set (e.g., the first compression block set 321 or the second compression block set 322 of the plurality of compression block sets 320 of FIG. 3).

The metadata 720 may include position information corresponding to a compression block set of a plurality of compression block sets corresponding to each parallel decoder of a plurality of parallel decoders. The position information may include a start word, a start offset, and a start index. The start word of the metadata 720 may include information about a first word of decompressed data corresponding to a compression block set allocated to a parallel decoder. The start offset of the metadata 720 may include information about a position of the first word of the decompressed data corresponding to the compression block set allocated to the parallel decoder. The start index of the metadata 720 may include information about a position where the decompressed data corresponding to the compression block set allocated to the parallel decoder among the entire decompressed data starts.

The compression block set allocated to the parallel decoders shown in FIG. 7 may each include 20 compression blocks. A first compression block to a 20th compression block, a 21st compression block to a 40th compression block, a 41st compression block to a 60th compression block, and a 71st compression block to an 80th compression block may each be grouped into a compression block set. The electronic device may select metadata corresponding to the first compression block of each compression block set. In the example shown in FIG. 7, the electronic device may generate the metadata 720 by selecting metadata of the first compression block, the 21st compression block, the 41st compression block, and the 61st compression block, which are a portion of the metadata 710.

The electronic device may decompress the plurality of compression blocks based on the metadata. When the electronic device decompresses the plurality of compression blocks based on the metadata 710, metadata overhead may occur as many as encoding bits of the start word, the start offset, and the start index corresponding to the number (80) of compression blocks of the plurality of compression blocks. When the electronic device decompresses the plurality of compression blocks based on the metadata 720, metadata overhead may occur as many as encoding bits of the start word, the start offset, the start index, and the number of compression blocks corresponding to the number (4) of parallel decoders of the plurality of parallel decoders. The number of parallel decoders of the plurality of parallel decoders may be less than the number of compression blocks of the plurality of compression blocks. The electronic device of one or more embodiments may reduce overhead by generating the metadata 720 and decompressing the plurality of compression blocks based on the metadata 720 instead of the metadata 710, as the overhead caused by the metadata 720 may be less than the overhead caused by the metadata 710.

In an example, the electronic device may receive metadata (e.g., the metadata 720) corresponding to each parallel decoder of the plurality of parallel decoders instead of metadata (e.g., the metadata 710) corresponding to the plurality of compression blocks, along with the plurality of compression blocks. In an example, when generating compressed data and transmitting and storing the compressed data to and in a server, the electronic device may transmit and store metadata (e.g., the metadata 720) corresponding to each parallel decoder of the plurality of parallel decoders together, instead of metadata (e.g., the metadata 710) corresponding to the plurality of compression blocks. A size of the metadata may affect a compression ratio because it is included in a size of the compressed data. By transmitting and receiving the metadata 720 corresponding to each parallel decoder of the plurality of parallel decoders instead of the metadata 710 corresponding to the plurality of compression blocks that affects the compression ratio, the electronic device of one or more embodiments may increase the compression ratio of the compressed data.

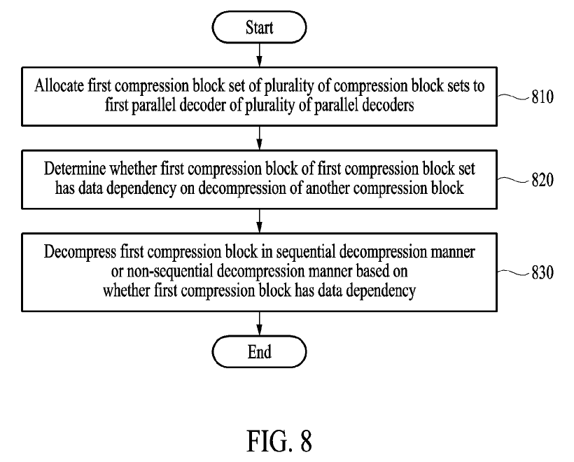

FIG. 8 illustrates an example of a decompression method using a plurality of parallel decoders according to one or more embodiments. Although one or more of operations of FIG. 8 are illustrated as being performed sequentially, one or more of the operations may be performed in a different order, one or more of the operations may be omitted, two or more of the operations may be performed in parallel or simultaneously, and/or other operations may be additionally performed without departing from the spirit and scope of the described embodiments.

In operation 810, the electronic device may allocate a first compression block set of a plurality of compression block sets to a first parallel decoder of a plurality of parallel decoders. The plurality of parallel decoders may be decoders that simultaneously perform decompression of compression blocks allocated to each parallel decoder. The electronic device may allocate a second compression block set of the plurality of compression block sets to a second parallel decoder of the plurality of parallel decoders. The number of parallel decoders of the plurality of parallel decoders may be less than the number of compression blocks of the plurality of compression block sets. The electronic device may determine the plurality of compression block sets by grouping the compression blocks of the plurality of compression block sets based on the number of compression blocks of the plurality of compression block sets and the number of parallel decoders of the plurality of parallel decoders.

In operation 820, the electronic device may determine whether a first compression block of the first compression block set has data dependency on decompression of another compression block. The data dependency on the decompression of the other compression block may be dependency on decompressed data generated by the decompression of the other compression block. The electronic device may determine whether the first compression block has the data dependency on the decompression of the second compression block of the second compression block set. The electronic device may determine a decompression status of the second compression block when the first compression block has the data dependency on the decompression of the second compression block.

In operation 830, the electronic device may decompress the first compression block in a sequential decompression manner or a non-sequential decompression manner based on whether the first compression block has the data dependency. For example, in operation 830, the electronic device may select either the sequential decompression manner or the non-sequential decompression manner depending on whether the first compression block has the data dependency, and may decompress the first compression block in the selected manner. The electronic device may decompress the first compression block in the non-sequential decompression manner when the first compression block has the data dependency on the decompression of the second compression block. The electronic device may decompress the first compression block in the sequential decompression manner when the first compression block does not have the data dependency on the decompression of the second compression block. The electronic device may decompress the first compression block in the sequential decompression manner when the first compression block has the data dependency on the decompression of the second compression block and the decompression status indicates completion of the decompression of the second compression block. The electronic device may decompress the first compression block in the non-sequential decompression manner when the first compression block has the data dependency on the decompression of the second compression block and the decompression status does not indicate completion of the decompression of the second compression block.

The electronic device may skip the decompression of a portion of the first compression block having the data dependency. The electronic device may sequentially decompress a portion of the first compression block not having the data dependency. The electronic device may monitor the decompression status of the second compression block. The electronic device may monitor the decompression status of the second compression block before performing the decompression of each compression block of the first compression block set including the first compression block. The electronic device may monitor whether reference decompressed data corresponding to the second compression block to be used for decompression of the portion of the first compression block having the data dependency is available, as at least a portion of the second compression block is decompressed. The electronic device may decompress a portion of the first compression block, in which the decompression is skipped, when the decompression status indicates the completion of the decompression of the second compression block. The electronic device may decompress the portion of the first compression block, in which the decompression is skipped, when the decompression status indicates the availability of the reference decompressed data.

The electronic device may receive metadata corresponding to compression blocks of the plurality of compression block sets. The electronic device may generate metadata corresponding to each parallel decoder of the plurality of parallel decoders by selecting a portion of the metadata corresponding to the compression blocks of the plurality of compression block sets. The electronic device may generate metadata corresponding to each parallel decoder of the plurality of parallel decoders. The metadata may include position information corresponding to a compression block set of the plurality of compression block sets corresponding to each parallel decoder of the plurality of parallel decoders. The electronic device may decompress the first compression block in the sequential decompression manner or the non-sequential decompression manner based on metadata corresponding to the first parallel decoder and whether the first compression block has the data dependency.

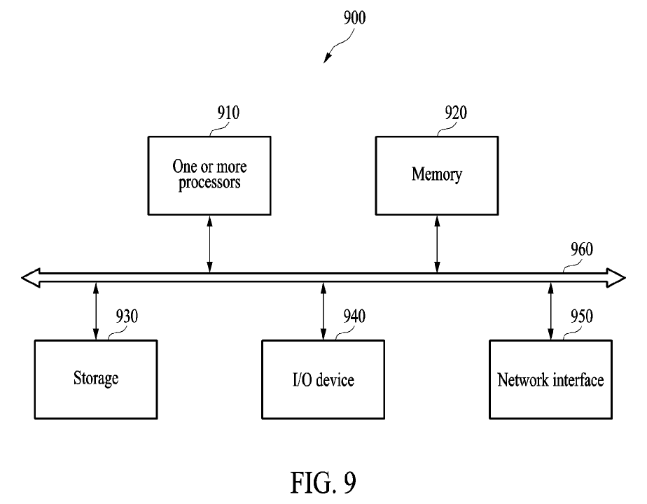

FIG. 9 illustrates an example of a configuration of an electronic device that performs decompression using a plurality of parallel decoders according to one or more embodiments. Referring to FIG. 9, an electronic device 900 may include one or more processors 910, a memory 920 (e.g., one or more memories), a storage 930, an input/output (I/O) device 940, and a network interface 950. These components may communicate with each other via a communication bus 960. For example, the electronic device 900 may be embodied as at least a portion of a mobile device (e.g., a mobile phone, a smartphone, a personal digital assistant (PDA), a netbook, a tablet computer, a laptop computer, etc.), a wearable device (e.g., a smartwatch, a smart band, smart eyeglasses, etc.), a computing device (e.g., a desktop, a server, etc.), a home appliance (e.g., a television (TV), a smart TV, a refrigerator, etc.), a security device (e.g., a door lock, etc.), and/or a vehicle (e.g., an autonomous vehicle, a smart vehicle, etc.).

The one or more processors 910 may execute instructions stored in the memory 920 or the storage 930. When executed by the one or more processors 910, the instructions may cause the electronic device 900 to perform the operations described with reference to FIGS. 1-8. The memory 920 may include a computer-readable storage medium or a computer-readable storage device. The memory 920 may store instructions to be executed by the one or more processors 910 and may store related information while software and/or an application is being executed by the electronic device 900. For example, the memory 920 may be or include a non-transitory computer-readable storage medium storing instructions that, when executed by the one or more processors 910, configure the one or more processors 910 to perform any one, any combination, or all of the methods and/or operations disclosed herein with reference to FIGS. 1-9.

The storage 930 may include a non-transitory computer-readable storage medium or a non-transitory computer-readable storage device. The storage 930 may store a greater amount of information than the memory 920 for a longer period of time. For example, the storage 930 may include a magnetic hard disk, an optical disc, a flash memory, a floppy disk, and/or any other form of non-volatile memory known in the art.

The I/O device 940 may receive an input from a user in traditional input manners through a keyboard and a mouse, and in new input manners, such as a touch input, a voice input, and an image input. For example, the I/O device 940 may include a keyboard, a mouse, a touch screen, a microphone, and/or any other device that detects the input from the user and transmits the detected input to the electronic device 900. The I/O device 940 may provide an output of the electronic device 900 to the user through a visual, auditory, and/or haptic channel. The I/O device 940 may include, for example, a display, a touch screen, a speaker, a vibration generator, and/or any other device that provides the output to the user. The network interface 950 may communicate with an external device through a wired or wireless network.

The electronic devices, servers, one or more processors, memories, storages, I/O devices, network interfaces, communication buses, electronic device 101, server 102, electronic device 900, one or more processors 910, memory 920, storage 930, I/O device 940, network interface 950, and communication bus 960 described herein, including descriptions with respect to respect to FIGS. 1-9, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit (ALU), a digital signal processor (DSP), a microcomputer, a programmable logic controller, a field-programmable gate array (FPGA), a programmable logic array (PLU), a microprocessor, or any other device or combination of devices that is configured to respond to and execute instructions (e.g., code or coding) in a defined manner to achieve a desired result. In one example, a processor or computer includes, or is connected to, one or more memories storing the instructions or software that are executed by the processor or computer. Hardware components implemented by a processor or computer may execute the instructions or software, such as an operating system (OS) and one or more software applications that run on the OS, to perform the operations described in this application. The hardware components may also access, manipulate, process, create, and store data in response to execution of the instructions or software. For simplicity, the singular term "processor" or "computer" may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing. Thus, references to a processor herein mean processing circuitry (e.g., circuitry that includes one or more processing element(s) circuits). One or more processors comprising processing circuitry also refers to each processor comprising processing circuitry, as well as some or all of the one or more processors comprising the same processing circuitry. In addition, processors(s) and controller(s), as a non-limiting example, do not mean human processing or human control, but rather, refer to hardware components as described herein, as non-limiting examples.

The methods illustrated in, and discussed with respect to, FIGS. 1-9 that perform the operations described in this application are performed by computing hardware, for example, by one or more processors or computers, implemented as described above implementing the instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations). Likewise, a reference to a processor-implemented method is a reference to a method that is performed by one or more processors or other processing or computing hardware of a device or system.

The instructions or software to control computing hardware, for example, one or more processors or computers, to implement the hardware components and perform the methods as described above may be written as computer programs, code segments, or other executable instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. Thus, references herein to storage media mean storage media hardware, and does not mean transitory media, nor a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD- Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks , and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method comprising:
allocating a first compression block set of a plurality of compression block sets to a first parallel decoder of a plurality of parallel decoders;
determining whether a first compression block of the first compression block set has data dependency on decompression of another compression block; and
decompressing the first compression block using a decompression manner determined as either a sequential decompression or a non-sequential decompression, the decompression manner being determined based on whether the first compression block has the data dependency.

2. The method of claim 1, wherein
the plurality of parallel decoders are decoders that simultaneously perform decompression of compression blocks allocated to each parallel decoder, and
the data dependency on the decompression of the other compression block is dependency on decompressed data generated by the decompression of the other compression block.

3. The method of claim 1,
further comprising allocating a second compression block set of the plurality of compression block sets to a second parallel decoder of the plurality of parallel decoders,
wherein the determining of whether the first compression block has the data dependency comprises determining whether the first compression block has the data dependency on decompression of the second compression block of the second compression block set.

4. The method of claim 3, wherein the decompressing of the first compression block comprises:
decompressing the first compression block using the non-sequential decompression in response to the first compression block having the data dependency on the decompression of the second compression block; and
decompressing the first compression block using the sequential decompression in response to the first compression block not having the data dependency on the decompression of the second compression block.

5. The method of claim 4, further comprising:
verifying a decompression status of the second compression block in response to the first compression block having the data dependency on the decompression of the second compression block; and
decompressing the first compression block using the sequential decompression in response to the first compression block having the data dependency on the decompression of the second compression block and the decompression status indicating completion of the decompression of the second compression block,
wherein the decompressing of the first compression block using the non-sequential decompression comprises decompressing the first compression block using the non-sequential decompression in response to the first compression block having the data dependency on the decompression of the second compression block and the decompression status not indicating the completion of the decompression of the second compression block.

6. The method of claim 4, wherein the decompressing of the first compression block using the non-sequential decompression comprises:
skipping decompression of a portion of the first compression block having the data dependency; and
sequentially decompressing a portion of the first compression block not having the data dependency.

7. The method of claim 6, wherein the decompressing of the first compression block using the non-sequential decompression comprises:
monitoring a decompression status of the second compression block; and
decompressing a portion of the first compression block, in which the decompression is skipped, in response to the decompression status indicating completion of the decompression of the second compression block.

8. The method of claim 7, wherein the monitoring of the decompression status comprises monitoring the decompression status of the second compression block before performing decompression of each compression block of the first compression block set comprising the first compression block.

9. The method of claim 7, wherein
the monitoring of the decompression status comprises monitoring whether reference decompressed data corresponding to the second compression block to be used for decompression of the portion of the first compression block having the data dependency is available, based on decompression of one or more portions of the second compression block, and
the decompressing of the portion of the first compression block, in which the decompression is skipped, comprises decompressing the portion of the first compression block, in which the decompression is skipped, in response to the decompression status indicating availability of the reference decompressed data.

10. The method of claim 1, wherein a number of parallel decoders of the plurality of parallel decoders is less than a number of compression blocks of the plurality of compression block sets.

11. The method of claim 10, further comprising determining the plurality of compression block sets by grouping the compression blocks of the plurality of compression block sets based on the number of compression blocks of the plurality of compression block sets and the number of parallel decoders of the plurality of parallel decoders.

12. The method of claim 1,
further comprising generating metadata corresponding to each parallel decoder of the plurality of parallel decoders,
wherein the metadata comprises position information corresponding to a compression block set of the plurality of compression block sets corresponding to each parallel decoder of the plurality of parallel decoders, and
the decompressing of the first compression block comprises decompressing the first compression block using the sequential decompression or the non-sequential decompression manner based on metadata corresponding to the first parallel decoder and whether the first compression block has the data dependency.

13. The method of claim 12, wherein the generating of the metadata comprises:
receiving metadata corresponding to compression blocks of the plurality of compression block sets; and
generating metadata corresponding to each parallel decoder of the plurality of parallel decoders by selecting a portion of the metadata corresponding to the compression blocks of the plurality of compression block sets.

14. An electronic device comprising:
one or more processors comprising processing circuitry; and
memory comprising one or more storage media storing instructions that, when executed individually or collectively by the one or more processors, cause the electronic device to:
allocate a first compression block set of a plurality of compression block sets to a first parallel decoder of a plurality of parallel decoders;
determine whether a first compression block of the first compression block set has data dependency on decompression of another compression block; and
decompress the first compression block using a decompression manner determined as either a sequential decompression or a non-sequential decompression, the decompression manner being determined based on whether the first compression block has the data dependency.

15. The electronic device of claim 14, wherein the execution of the instructions causes the electronic device to:
allocate a second compression block set of the plurality of compression block sets to a second parallel decoder of the plurality of parallel decoders; and
for the determining of whether the first compression block has the data dependency, determine whether the first compression block has the data dependency on decompression of the second compression block of the second compression block set.

16. The electronic device of claim 15, wherein, for the decompressing of the first compression block, the execution of the instructions causes the electronic device to:
decompress the first compression block using the non-sequential decompression in response to the first compression block having the data dependency on the decompression of the second compression block; and
decompress the first compression block using the sequential decompression in response to the first compression block not having the data dependency on the decompression of the second compression block.

17. The electronic device of claim 16, wherein, for the decompressing of the first compression block using the non-sequential decompression, the execution of the instructions causes the electronic device to:
skip decompression of a portion of the first compression block having the data dependency; and
sequentially decompress a portion of the first compression block not having the data dependency.

18. The electronic device of claim 17, wherein, for the decompressing of the first compression block, the execution of the instructions causes the electronic device to:
monitor a decompression status of the second compression block; and
decompress a portion of the first compression block, in which the decompression is skipped, in response to the decompression status indicating completion of the decompression of the second compression block.

19. The electronic device of claim 18, wherein, for the monitoring of the decompression status, the execution of the instructions causes the electronic device to monitor the decompression status of the second compression block before performing decompression of each compression block of the first compression block set comprising the first compression block.

20. A processor-implemented method comprising:
skipping decompression of a portion of a compression block, in response to the portion having data dependency on decompression of another compression block;
sequentially decompressing another portion of the compression block not having the data dependency, in response the portion having the data dependency; and
decompressing the portion having the data dependency, in response to the decompression of the other compression block being completed.
